(19) United States
(12) Patent Application Publication
(10) Pub. No.: US 2008/0285187 A1
(43) Pub. Date: Nov. 20, 2008

(54) CDM ESD PROTECTION FOR INTEGRATED CIRCUITS

(76) Inventors: Benjamin Van Camp, Antwerp (BE); Bart Sorgeloos, Affligem (BE)

Correspondence Address: PATENT DOCKET ADMINISTRATOR;LOWENSTEIN SANDLER P.C., 65 LIVINGSTON AVENUE, ROSELAND, NJ, 07068, US

(21) Appl. No.: 11/750,062

(22) Filed: May 17, 2007

(51) Int. Cl. H01L 23/58; H02H 9/00

(52) U.S. Cl. 361/56

(57) ABSTRACT

The present invention provides a charged-device model (CDM) electrostatic discharge (ESD) protection circuit for an integrated circuit (IC). The ESD protection circuit comprises a substrate of first conductivity type; a MOS component of second conductivity type formed on a first well on the substrate, and coupled to a pad; an isolating well/region having the second conductivity type being formed between the first well and the substrate to separate the first well and the substrate. Additionally, the circuit comprises an ESD clamp coupled to the isolated well/region. Under normal power operation, the ESD clamp is open. During a CDM ESD event, the CDM charges accumulated in the substrate and the MOS component are removed by the ESD clamp to prevent damage to the IC.

### FIELD OF THE INVENTION

This invention generally relates to the field of electrostatic discharge (ESD) protection circuitry and, more specifically, improvements against Charged Device Model (CDM) stress cases in the protection circuitry of the integrated circuit (IC).

### BACKGROUND OF THE INVENTION

Integrated circuits (ICs) and other semiconductor devices are extremely sensitive to the high voltages that may be generated by contact with an ESD event. As such, electrostatic discharge (ESD) protection circuitry is essential for integrated circuits. An ESD event commonly results from the discharge of a high voltage potential (typically, several kilovolts) and leads to pulses of high current (several amperes) of a short duration (typically, 100 nanoseconds). An ESD event can occur within an IC, illustratively, by human contact with the leads of the IC or by electrically charged machinery being discharged in other leads of an IC. During installation of integrated circuits into products, these electrostatic discharges may destroy or impair the function of the ICs and thus require expensive repairs on the products, which could have been avoided by providing a mechanism for dissipation of the electrostatic discharge to which the IC may have been subjected. When the IC itself is charged, discharge can happen even through a single pin of the IC substrate. This type of stress is modeled as the Charged Device Model (CDM).

There are various types of physical and chemical process to manufacture an IC. Many different processes exist, having many different process options. In many cases, one or more of these process options allow the creation of an isolated well. A well is considered ‘Isolated’ when it is possible to create a voltage difference between the well and the substrate.

To protect an IC against ESD, many different type of clamps exist. In general, these clamps exhibit low leakage (i.e. extremely high resistivity) during normal operation, and low resistivity during ESD. These clamps are connected to power pads and/or IO pads. Any pad which is connected to an outside pin should have some kind of ESD clamp attached to it. Also, even some pins inside the chip need some ESD protection. Some typical examples of pins are drivers and receivers connected between different power domains.

U.S. Pat. No. 6,885,529 discloses a CDM protection design using deep N-Well structure solving a CDM threat. The CDM threat in this patent is introduced because the functional device is placed directly in the substrate (not in an isolated well). Under CDM conditions, the substrate is filled with many electrostatic charges. This issue is solved by isolating the functional device from the substrate by introducing an isolating well. The functional device is placed within said isolating well, such that the charges in the substrate do not damage the functional device. A clamp between substrate and pad is placed to discharge the substrate. The U.S. Pat. No. 6,885,529 states that the charges in the isolated well in which the functional device is placed are ‘too few to damage the gate oxide’. This is however not true. Although the number of charges is limited, they can damage the gate oxide.

FIG. 1A illustrates a prior art cross-section diagram of an Integrated Circuit 100 for CDM ESD protection. The circuit 100 comprises a lightly doped region, such as a P-substrate 102 having a first conductivity type and first lightly doped regions, such as deep N-well 108 and the N-well 110 of the second conductivity type. The circuit further comprises a second lightly doped isolated region 106, preferably a P-well of the first conductivity type formed within the first lightly doped regions deep N-well 108 and N-well 110. Thus, as shown in FIG. 1A, the region 110 preferably forms a ring structure around the isolated region 106 and together with the N-well region 108 isolates the P-well region 106 from the substrate 102.

Referring back to FIG. 1A, the circuit further comprises a semiconductor device 104 such as a transistor, an exemplary MOSFET as shown in FIG. 1A. The transistor 104 is preferably formed in the second lightly doped isolated region 106, i.e. the isolated Pwell of the first conductivity type. The transistor 104 comprises a first heavily doped region 104a, a second heavily doped region 104b and a gate 104c. The gate is connected to a sensitive node 118 such as an input/output (I/O) pad leading to a periphery external to the circuit 100. The transistor 104 comprises a first heavily doped region of the second conductivity type in the case of the FIG. 1A N+ 104a and a second heavily doped region N+ 104b, also of the second conductivity type formed in the isolated well 106 of a the first conductivity type.

As shown as an example scenario in FIG. 1A, the N-well 110 and the Deep N-well are coupled to a first power supply, i.e. first voltage potential, 122, for example VDD. The P-substrate 102 is connected to a second power supply, i.e. second voltage potential 124, for example ground through a heavily doped region, P+ 120. The isolated P-well region 106 is connected to the second potential, 124 through a core circuitry 114. Thus, a heavily doped region P+ 116 is added. The region 116 will make a low ohmic path between the isolated region 106 and the core circuitry 114. The transistor 104 is preferably connected to the potentials 122 and 124 through the core circuitry 114. The core circuitry 114 may preferably be transistors, resistors, inductors, capacitors, metals, etc. The core circuitry 114 is placed accordingly to fulfill requirement for the normal operation and its function depends on the application.

Additionally as illustrated in FIG. 1A, clamps represented as diodes 126 are placed between the sensitive node, I/O pad 118 and the power supply 122 or 124. The diodes are added to protect the gate 104c for ESD stress. Although, not shown in this figure, but other ESD protection elements such as local clamps can preferably be placed between the node 118 and the power supply 122 or 124. The failure under CDM stress conditions is possible for this diagram as described herein below.

Referring to FIGS. 1B, 1C and 1D, there is shown a working example for the IC circuit 100 of FIG. 1A. Specifically, FIG. 1B illustrates an explanation of CDM for the IC circuit 100 of FIG. 1A before CDM. Before the CDM event happens, the IC is charged up. This means that charges 132 (i.e. positive charges for positive CDM, negative charges for negative CDM) are stored all over the IC 100, and thus also in the isolated p-well region 106. During CDM, the charges inside the P-substrate 102 and deep Nwell 108 typically have a low resistive path to the supply lines 122 and 124. So, during CDM, the charges 132 from the P-substrate 102 and deep N-well 108 can typically flow easily to supply lines 122 or 124 as illustrated in FIG. 1C. However, this case scenario does not occur for the charges 132 inside the isolated P-well region 106 as shown in FIG. 1D. These charges 132 will either flow through a core circuitry 114 or through the gate oxide 104c, depending on the resistivity of the core circuitry 114, thickness of the gate oxide and CDM stress level. If the charges 132 flow through the core circuitry 114, damage of the IC 100 is possible due to inefficient ESD protection from the core circuitry 114. If the charges 132 flow through the gate oxide, damage of the IC 100 is also almost certain. As illustrated in FIG. 1D, the gate oxide of the gate 104c will be damaged. Therefore, these isolated wells, exemplary, P-well isolated region 106 can pose a threat to the IC 100 during CDM stress.

Thus, there is a need in the art to provide an improved electrostatic discharge (ESD) protection circuitry, specifically, improvement against Charged Device Model (CDM) stress cases in the protection circuitry of the integrated circuit (IC).

### BRIEF DESCRIPTION OF THE DRAWINGS

FIG. 1A depicts an illustration of a prior art cross-section diagram of an Integrated Circuit for CDM ESD protection

FIG. 1B depicts an illustrative prior art cross-section diagram of FIG. 1A when the chip is charged

FIG. 1C depicts an illustrative prior art cross-section diagram of FIG. 1A during CDM.

FIG. 1D depicts an illustrative prior art cross-section diagram of FIG. 1A during CDM.

FIG. 2A depicts an illustrative cross-section diagram of an Integrated Circuit with CDM ESD protection in accordance with one embodiment of the present invention.

FIG. 2B depicts an illustrative cross-section diagram of FIG. 2A during CDM in accordance with the embodiment of the present invention.

FIG. 2C depicts an illustrative exemplary cross-section diagram of FIG. 2A in accordance with alternate embodiment of the present invention.

FIG. 2D depicts an illustrative cross-section diagram of FIG. 2A in accordance with another alternate embodiment of the present invention.

FIG. 2E depicts an illustrative cross-section diagram of a further alternate embodiment with reference to FIG. 2A of the present invention.

### SUMMARY OF THE INVENTION

In one embodiment of the present invention, there is provided a circuit having charged-device model (CDM) electrostatic discharge (ESD) protection comprising a substrate, a semiconductor device isolated from the substrate and an ESD clamp device coupled to the device to discharge the charges located in the device.

In a preferred embodiment of the present invention, there is provided a circuit having charged-device model (CDM) electrostatic discharge (ESD) protection comprising a substrate of first conductivity type, a first lightly doped region of second conductivity type formed within the substrate and a second lightly doped region formed within the first lightly doped region. The second lightly doped region of the first conductivity type. The circuit further comprises a semiconductor device formed in the second lightly doped region and an ESD clamp device coupled between the second lightly doped region and a reference node.

### DETAILED DESCRIPTION OF THE INVENTION

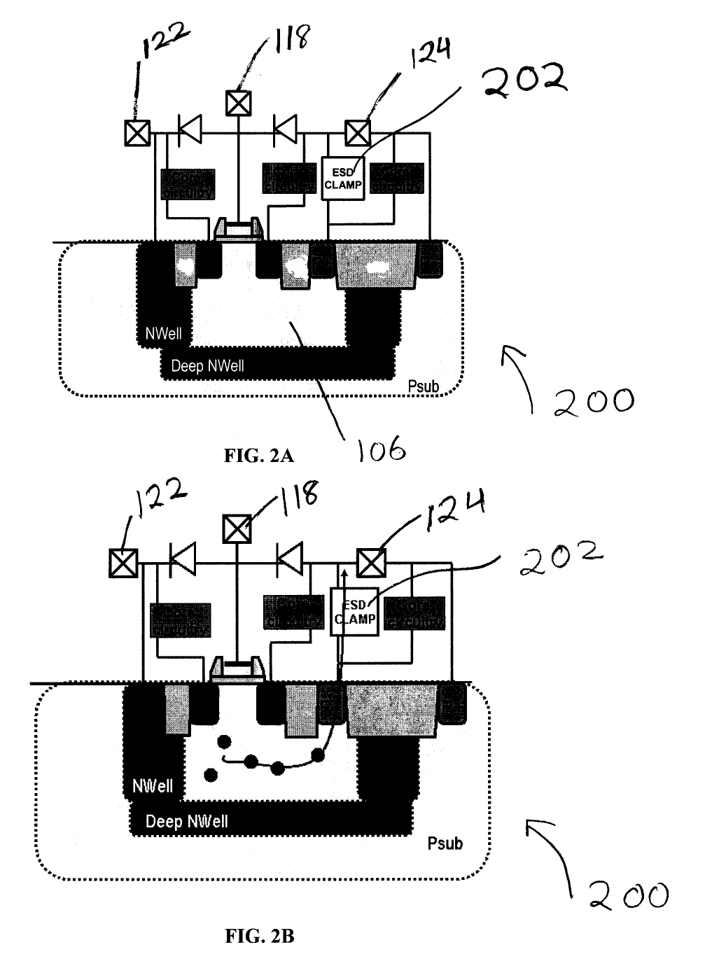

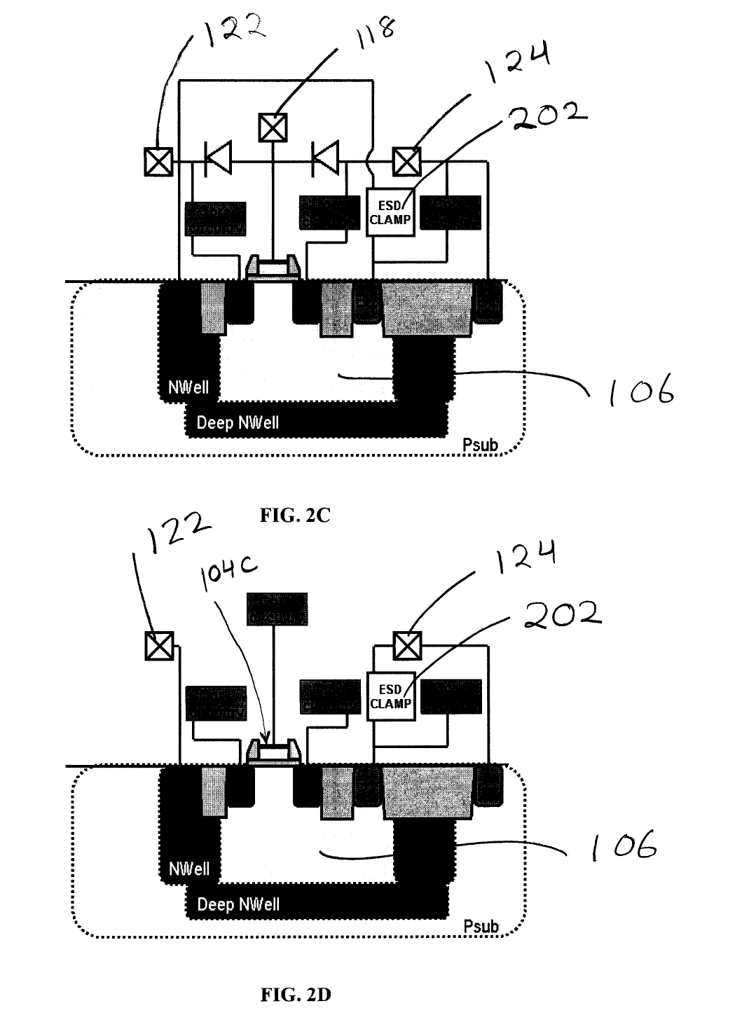

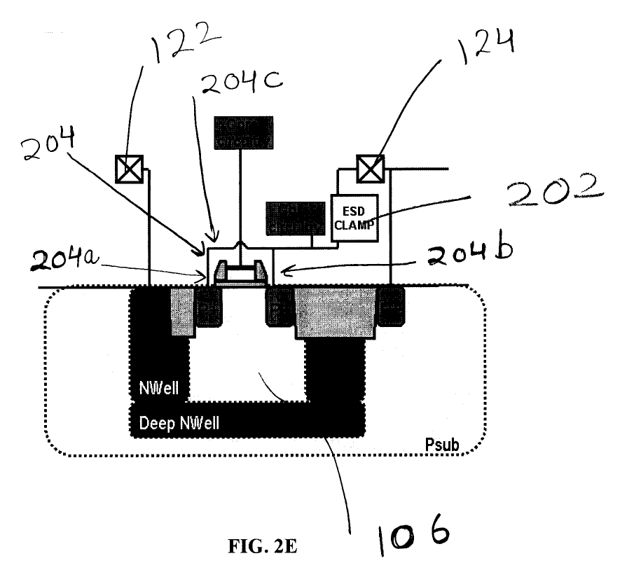

The invention relates to a technique to increase the CDM performance of an IC by connecting additional ESD clamps to isolated wells (or junctions). FIG. 2A illustrates a cross-section diagram of an Integrated Circuit IC 200 for CDM ESD protection in accordance with one embodiment of the present invention. The IC 200 illustrates a cross-section diagram of the transistor 104 formed in the isolated P-well region 106 with the deep N-well 108 and N-well 110 forming a ring structure around the isolated region to isolate/separate the P-well region 106 from the P-substrate 104. Furthermore, an additional ESD clamp 202 is coupled to the isolated P-well, 106 as shown in FIG. 2A. Specifically, the ESD clamp 202 is placed between the isolated P-well 106 and a reference node. The selection of the reference node depends on the normal operation requirements such as noise, cross-coupling, and other ESD elements. Preferably for ESD and in this example of FIG. 2A, the terminal to the isolated well 106 is coupled to the second potential 124 (i.e. the reference node) with the ESD clamp 202. Depending on the normal operation requirements the ESD clamp 202 may preferably comprise one of: SCR (with or without trigger device), MOS, diode, resistor, or other elements. As discussed above, one implementation is that the second potential 124 is one of the ground lines. However, there exist a lot of cases where the isolated well 106 is coupled to another ground besides the ground potential 124. This is preferably due to normal operation requirements such as noise. Now the voltage of the isolated well 106 is nearly equal to the second potential 124 and so one or more diodes in series can be utilized as ESD clamp 202. However there are also other possible cases where the voltage difference between the isolated well 106 and the second potential 124 is larger during normal operation or there are some other more severe requirements. In those cases, other elements such as SCR, transistor, resistor, capacitor or inductor are preferably utilized as the ESD clamp 202 to remove the charges of the isolated P-well 106.

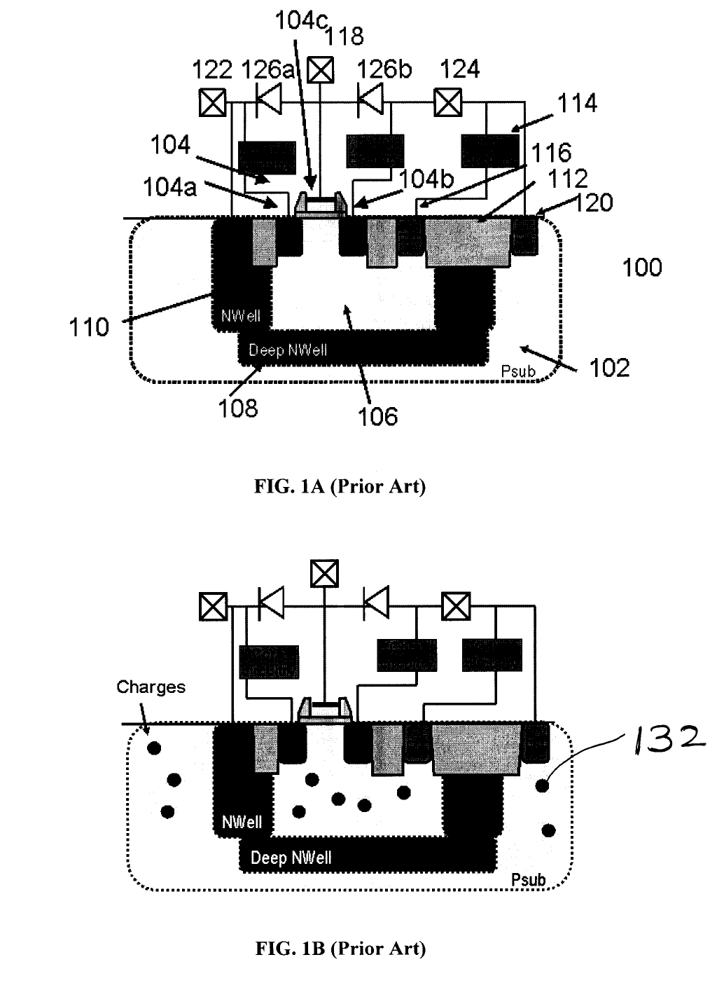

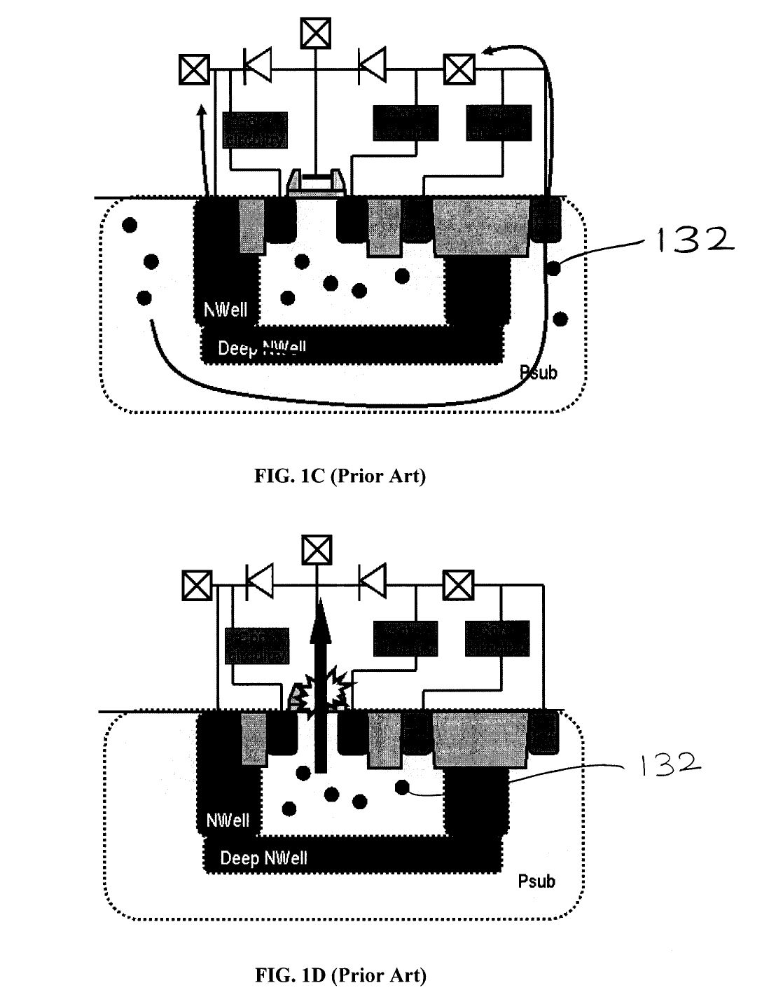

Referring to FIG. 2B, there is illustrated a cross-section diagram of IC 200 of FIG. 2A during CDM in accordance with the embodiment of the present invention. As shown in FIG. 2B, the ESD clamp 202 is added to remove the charges from the isolated P-well 106. Thus, during CDM, as shown in FIG. 2B, the charges 132 in the isolated P-well 106 are allowed to flow through the dedicated ESD path i.e. via the ESD clamp 202 to prevent the damage to either the core circuitry 114 or the gate oxide thus, avoiding the damage to the IC 100. As shown earlier in FIG. 1 C, the charges in the substrate 102 and in the N-Well 110 (and Deep N-Well Well 108) will flow easily to the node potentials 124 and 122 respectively. In an initial stage of the ESD discharge, the charges will remain in the isolated Well 106. Due to the difference in discharging between the substrate 102 and N-well 110 at one side and the isolated P-well 106 at the other side, a voltage difference will be created between the I/O pad 118 and the substrate 102. In the prior art the voltage built up will be large enough to damage the gate, but in this invention the ESD clamp 202 will turn on at a voltage below the gate oxide breakdown or the failure of the core circuitry 114. The triggering of the clamp 202 will further limit the voltage built-up over the gate oxide, thus protecting it, and will discharge the charges of the isolated well 106 to the reference node, (i.e. node potential 124 in FIG. 2A and FIG. 2B) and then ultimately to the I/O pad 118.

Note that the invention is not limited to the placement of the ESD clamp 202. FIG. 2C shows an exemplary cross-section diagram of IC 200 of FIG. 2A where the ESD clamp 202 is placed between the isolated P-well 106 and the first potential 122 instead of the second potential 124. Thus, in this example of FIG. 2C, the terminal to the isolated well 106 is coupled to the first potential 122 (i.e. the reference node) with the ESD clamp 202. For negative CDM this can be advantage such that if the ESD protection of the sensitive node comprises only the ESD diodes 126a and 126b and no local clamps, the charges in FIG. 2B will flow to the second potential 124. A power clamp (not shown) is always located between the first potential 122 and the second potential 124. Thus the charges in FIG. 2B will need to travel through the power clamp to the first potential 122, then, they will go through the diode 126a to the I/O pad 118. However, in this embodiment of the present invention, the charges will flow directly to the first potential 122, without any need to go through the power clamp anymore. The voltage built over the gate 104c will be now lower, i.e. having a less resistive path.

Referring to FIG. 2D there is shown an illustrative exemplary cross-section diagram of IC 200 of FIG. 2A utilizing the invention for the isolated well inside the core of the IC. In this example, the isolated well, i.e. P-well 106 is placed in the core of the IC 100, instead of in the periphery as illustrated in FIG. 2A. In the prior art, during CDM stress the internal node can discharge with a different speed than the isolated well 106, which creates as in the I/O pad 118, a voltage built-up over the gate 104c. So, in order to prevent gate damage, in the present embodiment, the charges in the isolated well 106 are preferably discharged also with an ESD clamp 202 coupled to another internal node. One example in FIG. 2D shows that the another internal node is one of the potentials, i.e. second potential 124 as described in FIG. 2A. Thus, in this application, the charges of the substrate 102 and the isolated well 106 will be discharged at the same rate. Although, as shown in FIG. 2D of the present embodiment, the gate 104c of the transistor 104 is connected to a core circuitry 114, it can also preferably be connected to the internal node.

Now referring to FIG. 2E, there is shown an illustrative exemplary cross-section diagram of IC 200 of FIG. 2A utilizing protecting another device, for example, a capacitance used to show the advantage of the technique described in the present invention. Thus, the problem that the isolated well 106 can not be discharged and will damage a device is not limited to transistors only. FIG. 2E illustrates a scenario where the device within the isolated Well, i.e. device 106 is a capacitance 204, instead of a transistor 104. The ESD clamp 202 is shown to be coupled between the potential node 124 and the isolated P-Well 106. In this case, the connection to the isolated well 106 (and 204a) is not a separate tap 116 but a part of the device. The charges will flow during the stress through the tap region 204a (or even through 204b, in this case these two taps are coupled together) to the ESD clamp 202. Further the charges will flow to the potential Vss 124 which in this figure is the output. When the charges has reached this potential, they can flow to the stressed pin (not shown) internal to the chip as described in the previous embodiments. It is important to note that those skilled in the art can utilize many other devices to utilize the above-described invention technique.

Although the invention is illustrated for an NMOS component, those skilled in the art would appreciate that a PMOS structure device can preferably be utilized. Furthermore, the present invention is not restricted for the use for an Isolated Pwell. Any well which is isolated from the Vss or Vdd busses or only connected to those busses through some core circuitry, requires the protection as described in this invention.

A typical case where this kind of protection might be appropriate beside technologies with deep n-well (or buried layer), is the case of silicon-on-insulator (SOI) integrated circuit, where the body region of the transistor is easily isolated from Vss and Vdd bus, since there is no substrate connection between the body region of the transistor (i.e. the well) and a ground connection. Other processes are for example bipolar technologies (BCD, HV technologies), where a lot of isolated wells are used.

Although various embodiments that incorporate the teachings of the present invention have been shown and described in detail herein, those skilled in the art can readily devise many other varied embodiments that still incorporate these teachings without departing from the spirit and the scope of the invention.

1. A circuit having charged-device model (CDM) electrostatic discharge (ESD) protection comprising:
a substrate;
a semiconductor device isolated from the substrate;
an ESD clamp coupled to the device to discharge charges located in the device, wherein said clamp triggers upon voltage build up in the device.

2. The circuit of claim 1 wherein the ESD clamp device comprise at least one of SCR, transistor, diode, resistor, capacitor, or inductor.

3. The circuit of claim 1 wherein said semiconductor device comprise a MOSFET having source, drain and gate, wherein said gate is connected to a I/O pad external to the circuit.

4. The circuit of claim 1 wherein said semiconductor device comprise a MOSFET having a source, drain and gate, wherein said gate is connected to an internal node.

5. The circuit of claim 1 wherein said semiconductor device comprise a capacitance connected internally to the circuit.

6. The circuit of claim 1 wherein said ESD clamp is coupled to a power supply.

7. A circuit having charged-device model (CDM) electrostatic discharge (ESD) protection comprising:
a substrate of first conductivity type;
a first lightly doped region of second conductivity type formed within the substrate;
a second lightly doped region formed within the first lightly doped region, said second lightly doped region of the first conductivity type;
a semiconductor device formed in the second lightly doped region;
an ESD clamp coupled between the second lightly doped region and a reference node to discharge charges located in the device, wherein said clamp triggers upon voltage build up in the device.

8. The circuit of claim 7 wherein the second lightly doped region is isolated from the substrate by the first lightly doped region.

9. The circuit of claim 7 wherein charges accumulated in the second lightly doped region flow via the ESD clamp during a CDM event.

10. The circuit of claim 7 wherein the device comprise at least one of transistor or capacitor.

11. The circuit of claim 7 wherein the ESD clamp comprise at least one of SCR, transistor, diode, resistor, capacitor, or inductor.

12. The circuit of claim 7 further comprising at least one power supply, wherein said reference node is one of the power supplies.

13. The circuit of claim 7 wherein said semiconductor device comprise a MOSFET having source, drain and gate, wherein said gate is connected to a I/O pad external to the circuit.

14. The circuit of claim 13 further comprising:
a first and second power supply, said reference node comprise one of the power supplies;
a first diode coupled between the I/O pad and the first power supply; and
a second diode coupled between the I/O pad and the second power supply.

15. The circuit of claim 13 wherein the MOSFET is part of an input driver of the I/O pad.

16. The circuit of claim 7 wherein said semiconductor device comprise a MOSFET having a source, drain and gate, wherein said gate is connected to an internal node.

17. The circuit of claim 7 wherein said semiconductor device comprise a capacitance connected internally to the circuit.

18. The circuit of claim 7 wherein the first conductivity type is an N type and the second conductivity type is a P type.

19. The circuit of claim 7 wherein the first conductivity type is a P type and the second conductivity type is a N type.

20. The circuit of claim 19 wherein the first lightly doped region is formed with a NWell region and with at least one of a Deep NWell region and buried layer
